(19) United States
(12) Patent Application Publication
(10) Pub. No.: US 2026/0231664 A1
(43) Pub. Date: Aug. 6, 2026

(54) THIN-FILM-FORMING APPARATUS AND ELECTRONIC DEVICE MANUFACTURED THEREBY

(71) Applicant: Samsung Display Co., Ltd., Yongin-si (KR)

(72) Inventors: Jin Won BAEK, Yongin-si (KR); Yeong Jun KIM, Yongin-si (KR); Lae Ho KIM, Yongin-si (KR); Bong Sik NOH, Yongin-si (KR); Tae Ho LEE, Yongin-si (KR); Myung Soo HUH, Yongin-si (KR); Dong Hoon HYUN, Yongin-si (KR)

(21) Appl. No.: 19/348,536

(22) Filed: Oct. 2, 2025

(30) Foreign Application Priority Data
Feb. 5, 2025 (KR) 10-2025-0014275

(51) Int. Cl. H10K 71/10; H10P 72/72

(52) U.S. Cl. CPC H10K 71/10; H10P 72/722

(57) ABSTRACT

A thin-film-forming apparatus includes an electrostatic chuck for supporting a substrate, and including a base portion, electrode patterns on the base portion, and ground patterns on the base portion and spaced apart from the electrode patterns, a supply nozzle for supplying a chemical onto the substrate, and a power supply for supplying power to the electrostatic chuck, and for selectively supplying power to one of the electrode patterns.

### CROSS-REFERENCE TO RELATED APPLICATION

The present application claims priority to, and the benefit of, Korean Patent Application No. 10-2025-0014275, filed on February 5, 2025, in the Korean Intellectual Property Office, the entire disclosure of which is incorporated herein by reference

### BACKGROUND

### 1. Field

The present disclosure relates to a thin-film-forming apparatus, and an electronic device manufactured thereby.

### 2. Description of the Related Art

An organic light-emitting display device is a display device using a phenomenon in which electrons injected from a cathode and holes injected from an anode recombine in an organic thin film to form excitons, and light of a corresponding wavelength is generated by energy from the formed excitons.

As a method of forming an organic material or metal used as an electrode in the organic light-emitting display device on a substrate, a chemical printing method may be used. The chemical printing method is a method of forming a thin film by supplying liquid chemical onto a substrate using a supply nozzle and curing the chemical supplied onto the substrate.

Because a plurality of protrusions may be formed on the substrate, a surface of the thin film may not be evenly formed during the process of forming the thin film by curing the chemical.

### SUMMARY

Aspects of the present disclosure provide a thin-film-forming apparatus capable of evenly forming a surface of the thin film and an electronic device manufactured thereby.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a thin-film-forming apparatus includes an electrostatic chuck for supporting a substrate, and including a base portion, electrode patterns on the base portion, and ground patterns on the base portion and spaced apart from the electrode patterns, a supply nozzle for supplying a chemical onto the substrate, and a power supply for supplying power to the electrostatic chuck, and for selectively supplying power to one of the electrode patterns.

The electrode patterns and the ground patterns may be alternately arranged with each other.

The electrode patterns and the ground patterns may extend in a first direction, wherein the electrode patterns and the ground patterns are spaced apart from each other in a second direction crossing the first direction.

End portions on one side of the electrode patterns may extend beyond the base portion in the first direction.

The end portions may extend in a third direction orthogonal to the first direction and to the second direction to cover a side surface of the base portion.

The power supply may include a moving member configured to move in the second direction outside of the base portion, and a power supply electrode for contacting the end portions according to the movement of the moving member, and for supplying power to the one electrode pattern.

The power supply electrode may be configured to rotate according to movement of the moving member.

The power supply may include a rotation shaft in the power supply electrode, an upper support member connected to an upper portion of the rotation shaft, a lower support member connected to a lower portion of the rotation shaft, and a connection member connecting the upper support member and the lower support member to the moving member.

The power supply may further include an elastic member between the connection member and the moving member and configured to push the power supply electrode toward the base portion.

The substrate may include flat portions, and protruding portions protruding above the flat portions, and alternately arranged with the flat portions.

The electrode patterns and the ground patterns may respectively overlap the protruding portions.

One of the electrode patterns may overlap one of the protruding portions, wherein one of the ground patterns overlaps another one of the protruding portions adjacent the one of the protruding portions with the flat portion.

The flat portions and the protruding portions may extend in the first direction, and are alternately arranged in the second direction.

The electrode pattern may be configured to receive an alternating current voltage, wherein the ground pattern is configured to receive a ground voltage.

The electrode patterns and the ground patterns may be configured to be retracted into the base portion from an upper surface of the base portion.

According to an aspect of the present disclosure, an electronic device includes a display device manufactured by a thin-film-forming apparatus including an electrostatic chuck for supporting a substrate, and including a base portion, electrode patterns on the base portion, and ground patterns on the base portion and spaced apart from the electrode patterns, a supply nozzle for supplying a chemical onto the substrate, and a power supply for supplying power to the electrostatic chuck, and for selectively supplying power to one of the electrode patterns.

The electrode patterns and the ground patterns may extend in a first direction, and may be spaced apart in a second direction crossing the first direction, wherein end portions on one side of the electrode patterns extend beyond the base portion in the first direction.

The power supply may include a moving member configured to move in the second direction outside of the base portion, and a power supply electrode for contacting the end portion on one side of one of the electrode patterns according to the movement of the moving member, and for supplying power to the one electrode pattern.

The power supply may further include a rotation shaft in the power supply electrode, an upper support member connected to an upper portion of the rotation shaft, a lower support member connected to a lower portion of the rotation shaft, and a connection member connecting the upper support member and the lower support member to the moving member.

The power supply may further include an elastic member between the connection member and the moving member, and configured to push the power supply electrode toward the base portion.

According to the thin-film-forming apparatus and the electronic device manufactured thereby according to the present disclosure, by arranging a plurality of electrode patterns and a plurality of ground patterns on an electrostatic chuck supporting the substrate, and by selectively supplying power to one of the plurality of electrode patterns, the surface of the chemical may be evenly maintained, thereby evenly forming the surface of the thin film formed on the substrate.

The aspects according to the embodiments of the present disclosure are not limited to those mentioned above, and more various aspects are included in the following description of the present disclosure.

### BRIEF DESCRIPTION OF THE DRAWINGS

The above and other aspects of the present disclosure will become more apparent by describing in detail example embodiments thereof with reference to the attached drawings, in which:

FIG. 1 is a view schematically illustrating a thin-film-forming apparatus according to one or more embodiments of the present disclosure;

FIG. 2 is a plan view of FIG. 1;

FIG. 3 is a plan view of an electrostatic chuck of FIG. 1;

FIG. 4 is an enlarged view of part A of FIG. 1;

FIG. 5 is a plan view of a power supply of FIG. 1;

FIG. 6 is a side view of FIG. 4;

FIG. 7 is a cross-sectional view taken along the line B-B’ of FIG. 5;

FIG. 8 is a view illustrating a state in which a supply nozzle supplies a chemical onto a substrate in FIG. 1;

FIG. 9 is an enlarged view of part C of FIG. 8;

FIG. 10 is a view illustrating a state in which a power supply electrode applies an AC voltage to one electrode pattern in FIG. 9;

FIG. 11 is a view illustrating a state in which a surface of the chemical has become even through the process of FIG. 10;

FIG. 12 is a plan view illustrating a bent state of a connection member of a display device manufactured by the thin-film-forming apparatus according to one or more embodiments of the present disclosure;

FIG. 13 is a view illustrating a state in which the connection member in FIG. 12 is unfolded;

FIG. 14 is a partial side view of FIG. 13;

FIG. 15 is a block diagram of an electronic device according to one or more embodiments;

FIG. 16 illustrates schematic diagrams of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

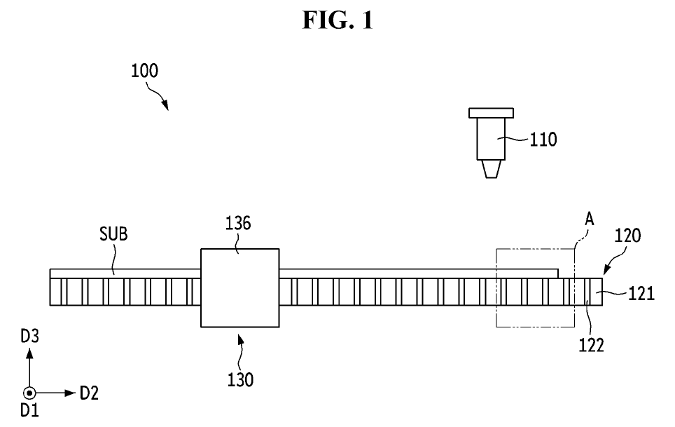

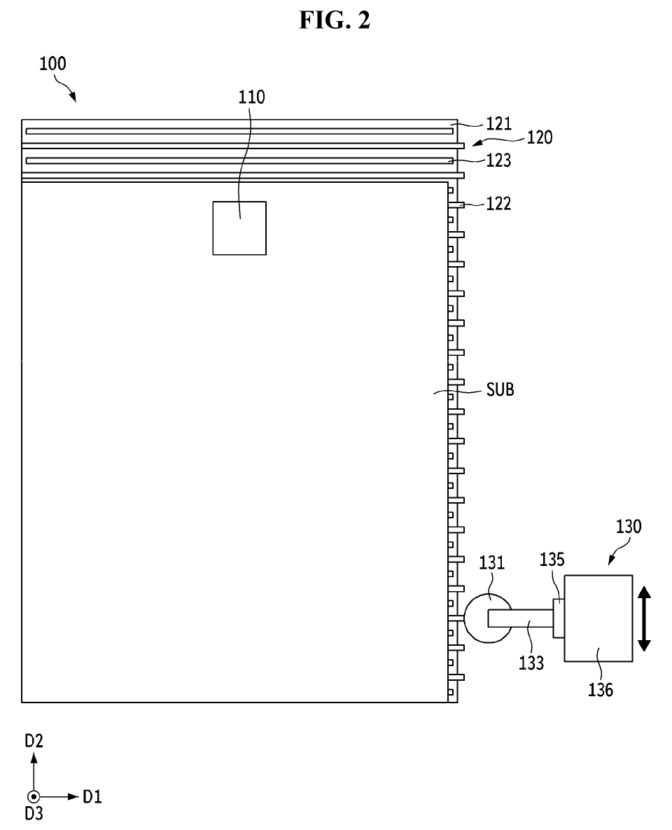

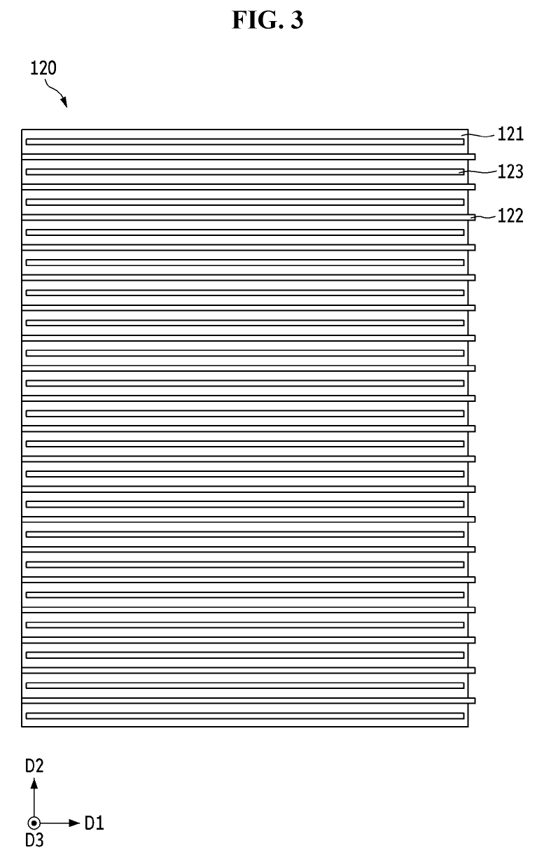

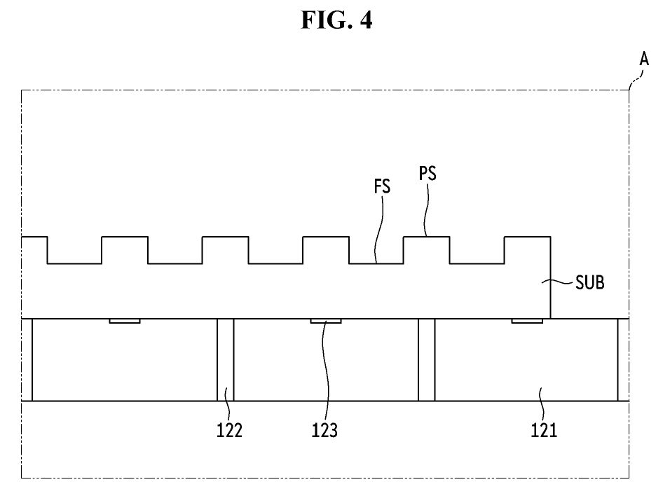

FIG. 1 is a view schematically illustrating a thin-film-forming apparatus according to one or more embodiments of the present disclosure. FIG. 2 is a plan view of FIG. 1. FIG. 3 is a plan view of an electrostatic chuck of FIG. 1. FIG. 4 is an enlarged view of part A of FIG. 1.

Referring to FIGS. 1 to 4, a thin-film-forming apparatus 100 according to one or more embodiments of the present disclosure may include a supply nozzle 110, an electrostatic chuck 120, and a power supply (e.g., power supply unit) 130.

The supply nozzle 110 may be located above a substrate SUB, and may supply a chemical MF onto the substrate SUB. The supply nozzle 110 may be horizontally movable above the substrate SUB, and may supply the chemical MF to an entire upper area of the substrate SUB. The supply nozzle 110 may be horizontally moved above the substrate SUB, but as the supply nozzle 110 is fixed and the substrate SUB is horizontally moved, the chemical MF may also be supplied to the entire upper area of the substrate SUB. In one or more embodiments, the supply nozzle 110 may be connected to a separate chemical storage (e.g., chemical storage unit) to receive the chemical MF from the chemical storage.

The electrostatic chuck 120 may support the substrate SUB. Before describing the electrostatic chuck 120, the substrate SUB supported by the electrostatic chuck 120 will first be described.

The substrate SUB may include an insulating material, such as glass, quartz, or a polymer resin. The substrate SUB may be a rigid substrate or a flexible substrate that may be bent, folded, and rolled. The substrate SUB may be provided as a rectangular plate having a pair of short sides extending in a first direction D1, and a pair of long sides extending in a second direction D2. In some embodiments, the substrate SUB may be a plate having a rectangular planar shape.

As shown in FIG. 4, the substrate SUB may include a flat portion FS and a protruding portion PS. The flat portion FS may be an upper surface of the substrate SUB, and the protruding portion PS may protrude from the flat portion FS upwardly/from an upper portion of the substrate SUB in a thickness direction. In some embodiments, the protruding portion PS may protrude from the flat portion FS in the third direction D3.

A plurality of flat portions FS and a plurality of protruding portions PS may be provided, and may be alternately arranged. For example, the plurality of flat portions FS and the plurality of protruding portions PS may extend in the first direction D1 and may be alternately located in the second direction D2.

The electrostatic chuck 120 may include a base portion 121, an electrode pattern 122, and a ground pattern 123.

The base portion 121 may be located on a lower portion of the substrate SUB and may support the substrate SUB (as used herein, “located on” may mean “beneath” in some instances, and may mean “above” in other instances). The base portion 121 may be provided as a rectangular plate having a pair of short sides extending in the first direction D1, and a pair of long sides extending in the second direction D2. In some embodiments, the base portion 121 may be a plate having a rectangular planar shape. A planar size of the base portion 121 may be greater than a planar size of the substrate SUB. The base portion 121 may include ceramic, but this is an example and the material of the base portion 121 may not be limited thereto. For example, the base portion 121 may include aluminum (Al), titanium (Ti), stainless steel, alumina (Al₂O₃), yttrium oxide (Y₂O₃), or aluminum nitride. The base portion 121 may support the electrode pattern 122 and the ground pattern 123.

The electrode pattern 122 may be located on an upper surface of the base portion 121. However, the electrode pattern 122 may also be retracted from the upper surface of the base portion 121 in the thickness direction of the base portion 121.

A plurality of electrode patterns 122 may be provided, and may be spaced apart from each other on the base portion 121. For example, the plurality of electrode patterns 122 may extend in the first direction D1 on the upper surface of the base portion 121, and the plurality of electrode patterns 122 extending in the first direction D1 may be spaced apart from each other in the second direction D2.

End portions on one side (right side in FIG. 3) of the plurality of electrode patterns 122 may extend to the outside of the base portion 121 in the first direction. The end portions on one side of the plurality of electrode patterns 122 may extend in the third direction D3 in the outside of (e.g., at the outside of, or beyond the outside of) the base portion 121. The end portions on one side of the plurality of electrode patterns 122 extending in the third direction D3 may cover a side surface of the base portion 121. The end portions on one side of the plurality of electrode patterns 122 extending in the third direction D3 may contact a power supply electrode 131 of the power supply 130, which will be described later.

An alternating current voltage may be applied to one of the plurality of electrode patterns 122 by the power supply 130. For example, when a surface of the chemical supplied onto the substrate SUB is uneven, a power supply electrode 131 of the power supply 130 contacts one end of an electrode pattern 122 that overlaps an area in which the surface of the chemical may be uneven, so that the alternating current voltage may be applied to the electrode pattern 122 that overlaps the area in which the surface of the chemical is uneven.

The ground pattern 123 may be located on the upper surface of the base portion 121. However, the ground pattern 123, may also be retracted from the upper surface of the base portion 121 in the thickness direction of the base portion 121.

A plurality of ground patterns 123 may be provided, and may be spaced apart from each other on the base portion 121. For example, the plurality of ground patterns 123 may extend in the first direction D1 on the upper surface of the base portion 121, and the plurality of ground patterns 123 extending in the first direction D1 may be spaced apart from each other in the second direction D2.

A ground voltage may be applied to the plurality of ground patterns 123 by a separate power source, in one or more embodiments.

The plurality of ground patterns 123 may be spaced apart from the plurality of electrode patterns 122. In some embodiments, the plurality of ground patterns 123 and the plurality of electrode patterns 122 may be located alternately with each other.

The above-described plurality of electrode patterns 122 and plurality of ground patterns 123 may overlap the plurality of protruding portions PS. One of the plurality of electrode patterns 122 may overlap one of the plurality of protruding portions PS, and one of the plurality of ground patterns 123 may overlap another protruding portion PS located in succession with one of the plurality of protruding portions PS overlapping one of the electrode patterns 122 with the flat portion FS. For example, if a protruding portion PS located on the far right side of FIG. 4 is called a first protruding portion PS, a protruding portion PS located on the left side of the first protruding portion PS is called a second protruding portion PS, a protruding portion PS located on the left side of the second protruding portion PS is called a third protruding portion PS, a protruding portion PS located on the left side of the third protruding portion PS is called a fourth protruding portion PS, a protruding portion PS located on the left side of the fourth protruding portion PS is called a fifth protruding portion PS, and a protruding portion PS located on the far left side of FIG. 4 is called a sixth protruding portion PS, then the first protruding portion PS may overlap the ground pattern 123, the second protruding portion PS may overlap the electrode pattern 122, the third protruding portion PS may overlap the ground pattern 123, the fourth protruding portion PS may overlap the electrode pattern 122, the fifth protruding portion PS may overlap the ground pattern 123, and the sixth protruding portion PS may overlap the electrode pattern 122. In this way, the plurality of electrode patterns 122 and the plurality of ground patterns 123 may overlap each of the plurality of protruding portions PS while alternating with each other.

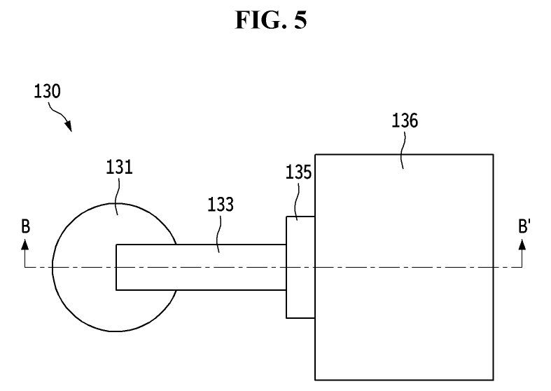

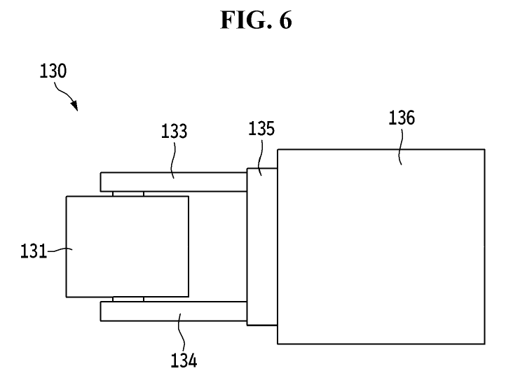

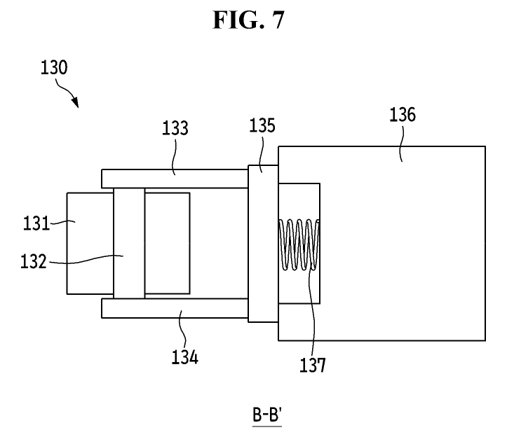

FIG. 5 is a plan view of a power supply of FIG. 1. FIG. 6 is a side view of FIG. 4. FIG. 7 is a cross-sectional view taken along the line B-B’ of FIG. 5.

Referring to FIGS. 5 to 7, the power supply 130 may selectively supply power to one of the plurality of electrode patterns 122. The power supply 130 may include a power supply electrode 131, a rotation shaft 132, an upper support member 133, a lower support member 134, a connection member 135, a moving member (e.g., an actuator) 136, and an elastic member 137.

The power supply electrode 131 may be a cylindrical electrode. In some embodiments, the power supply electrode 131 may have a cylindrical shape having a circular planar shape and a thickness. The power supply electrode 131 may have an outer periphery in contact with the side surface of the base portion 121, and may be selectively in contact with one of the plurality of electrode patterns 122 by being moved in the second direction D2 along the side surface of the base portion 121. The power supply electrode 131 may be formed in a hollow cylindrical shape with a hollow space formed, or defined, in a central portion thereof. The power supply electrode 131 may include a conductor capable of transmitting the power.

In addition, a diameter of the power supply electrode 131 may be less than a spacing between the plurality of electrode patterns 122 or a spacing between the plurality of ground patterns 123. A thickness of the power supply electrode 131 may be thinner than a thickness of the base portion 121.

The rotation shaft 132 may be inserted into the central hollow of the power supply electrode 131. A diameter of the rotation shaft 132 may correspond to a diameter of the central hollow of the power supply electrode 131. The rotation shaft 132 may be inserted into the central portion of the power supply electrode 131, and the power supply electrode 131 may rotate around the rotation shaft 132.

The upper support member 133 may be connected to one side of the rotation shaft 132. For example, the upper support member 133 may be connected to an upper side of the rotation shaft 132 in FIG. 6. The upper support member 133 may be provided as a plate having a thickness, and one side thereof may be connected to one side of the rotation shaft 132.

The lower support member 134 may be connected to the other side of the rotation shaft 132. For example, the lower support member 134 may be connected to a lower side of the rotation shaft 132 in FIG. 6. The lower support member 134 may be provided as a plate having a thickness, and one side thereof may be connected to the other side of the rotation shaft 132 (e.g., opposite to the one side of the rotation shaft 132 that is connected to the upper support member 133).

The connection member 135 may be connected to the upper support member 133 and the lower support member 134. For example, the connection member 135 may be connected to the other side of the upper support member 133 and to the other side of the lower support member 134 (e.g., opposite the sides of the upper support member 133 and the lower support member 134 that are connected to the rotation shaft 132) to fix the upper support member 133 and the lower support member 134. The connection member 135 may serve to connect the upper support member 133 and the lower support member 134 to the moving member 136.

The moving member (e.g., the actuator) 136 may be moved in the second direction D2 in the outside of the base portion 121. The moving member 136 may be connected to the connection member 135. As the connection member 135 is connected to the moving member 136, the power supply electrode 131 may be connected to the moving member 136. The moving member 136 may move the power supply electrode 131 in the second direction D2 by being moved in the second direction D2.

When the surface of the chemical supplied onto the substrate SUB is uneven, the moving member 136 may move the power supply electrode 131 so that the power supply electrode 131 contacts one end of the electrode pattern 122 that overlaps the area in which the surface of the chemical is uneven.

The elastic member 137 may be located between the connection member 135 and the moving member 136. A groove that is depressed inwardly may be formed in, or defined by, one end of the moving member 136, and the elastic member 137 may push the connection member 135 toward the base portion 121 while being retracted into the groove of the moving member 136. As the connection member 135 is pushed toward the base portion 121 by the elastic member 137, the power supply electrode 131 connected to the connection member 135 may be in close contact with the base portion 121. In some embodiments, the power supply electrode 131 and one end of the electrode pattern 122 may be in close contact with each other by the elastic member 137.

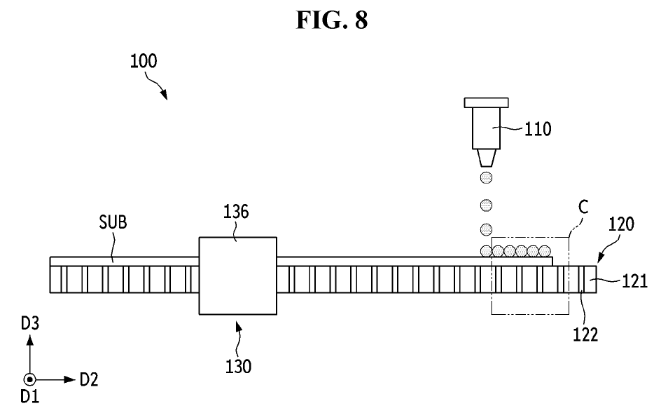

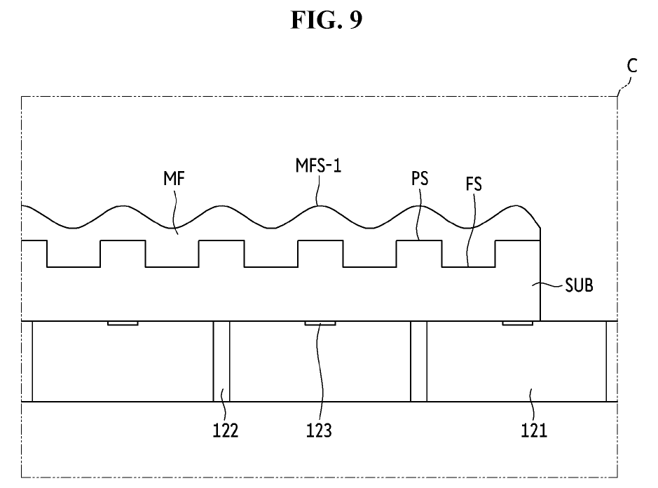

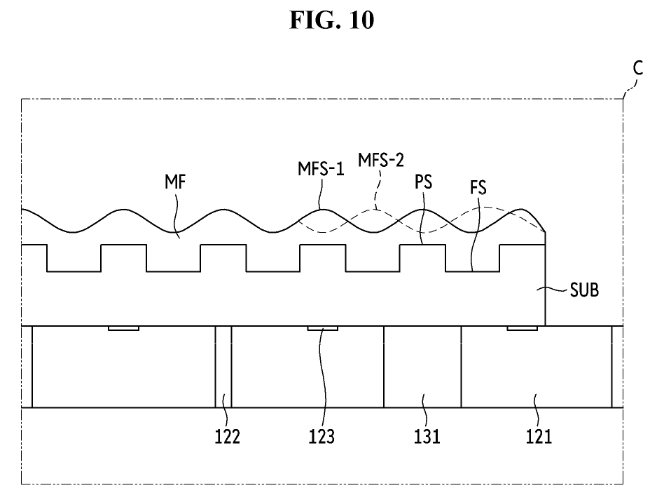

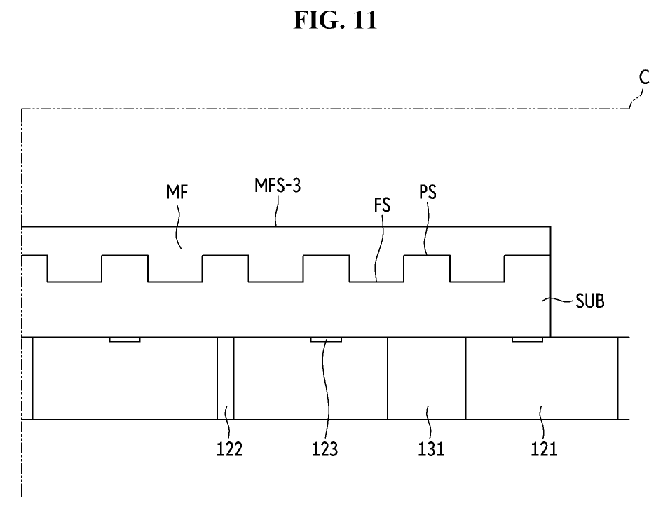

FIG. 8 is a view illustrating a state in which a supply nozzle supplies a chemical onto a substrate in FIG. 1. FIG. 9 is an enlarged view of part C of FIG. 8. FIG. 10 is a view illustrating a state in which a power supply electrode applies an AC voltage to one electrode pattern in FIG. 9. FIG. 11 is a view illustrating a state in which a surface of the chemical has become even through the process of FIG. 10.

Hereinafter, a process of forming a thin film on an upper portion of the substrate SUB by the thin-film-forming apparatus 100 according to one or more embodiments of the present disclosure will be described with reference to FIGS. 8 to 11.

Referring to FIG. 8, a chemical MF may be supplied to the upper surface of the substrate SUB by the supply nozzle 110. The supply nozzle 110 may horizontally move above the substrate SUB, and may supply the chemical MF to an entire area of the upper surface of the substrate SUB.

Referring to FIG. 9, an area where a surface of the chemical MF becomes uneven due to a step difference of the surface of the substrate SUB may be generated on the surface of the chemical MF supplied to the upper surface of the substrate SUB by the supply nozzle 110. For example, a surface MFS-1 of the chemical MF in the area where the protruding portion PS of the substrate SUB is positioned may protrude upwardly, or in an upper direction of the substrate SUB, and a surface of the chemical MF in the area where the flat portion FS of the substrate SUB is positioned may be depressed in a lower direction of the substrate SUB (e.g., to have a height that is lower than that of the surface of the chemical MF in the area where the protruding portion PS is located). In some embodiments, the surface MFS-1 of the chemical MF may be uneven due to the step difference of the surface of the substrate SUB.

Referring to FIGS. 10 and 11, the power supply 130 is moved toward the electrode pattern 122 that overlaps the second protruding portion PS among the plurality of protruding portions PS, and the power supply electrode 131 contacts the electrode pattern 122 that overlaps the second protruding portion PS, so that an alternating current voltage may be applied to the electrode pattern 122 that overlaps the second protruding portion PS.

In this way, when the alternating current voltage is applied to the electrode pattern 122 that overlaps the second protruding portion PS, a potential difference may be generated between the electrode pattern 122 that overlaps the second protruding portion PS and the ground patterns 123 located on respective sides of the electrode pattern 122. For example, a voltage of about -2 kV is applied to the electrode pattern 122 that overlaps the second protruding portion PS, and a voltage of about 0 kV is applied to the ground patterns 123 on the respective sides of the electrode pattern 122, so that a potential difference may be generated between the electrode pattern 122 that overlaps the second protruding portion PS and the ground patterns 123. In this case, Because the chemical MF may flow from a high voltage to a low voltage, a surface MFS-2 of the chemical MF in the area where the flat portion FS of the substrate SUB is positioned may protrude in the upper direction of the substrate SUB.

When the power supply electrode 131 supplies a voltage at regular intervals to the electrode pattern 122 that overlaps the second protruding portion PS, a phenomenon in which the surface MFS-1 of the chemical MF in the area where the second protruding portion PS is positioned protrudes toward the upper portion of the substrate SUB, and then the surface MFS-2 of the chemical MF in the area where the flat portions FS on the respective sides of the second protruding portion PS are positioned protrudes toward the upper portion of the substrate SUB may repeatedly occur. In this way, in the process of changing the surface of the chemical MF, a surface MFS-3 of the chemical MF may become flat, as illustrated in FIG. 11. In some embodiments, an upper surface of the chemical MF may be evenly maintained. As the upper surface of the chemical MF is evenly maintained, a surface of the thin film formed on the substrate SUB may be evenly formed.

The process of forming the thin film described above describes a case in which the area where the surface of the chemical MF is uneven is generated near the second protruding portion PS. If the area where the surface of the chemical MF is uneven is generated near the fourth protruding portion PS, the power supply 130 is moved toward the electrode pattern 122 that overlaps the fourth protruding portion PS, and the power supply electrode 131 contacts the electrode pattern 122 that overlaps the fourth protruding portion PS, so that an alternating current voltage may be applied to the electrode pattern 122 that overlaps the fourth protruding portion PS.

Because the process of evenly forming the area where the surface of the chemical MF is uneven formed near the fourth protruding portion PS is performed through the same process as the process of evenly forming the area where the surface of the chemical MF is uneven formed near the second protruding portion PS, a detailed description thereof will be omitted.

In this way, if an area where the surface of the chemical MF is uneven is generated, the thin-film-forming apparatus 100 according to one or more embodiments of the present disclosure may selectively apply the alternating current voltage to only the electrode pattern 122 near the area by the power supply 130, thereby performing an operation of substantially flattening the surface of the chemical MF only in the area.

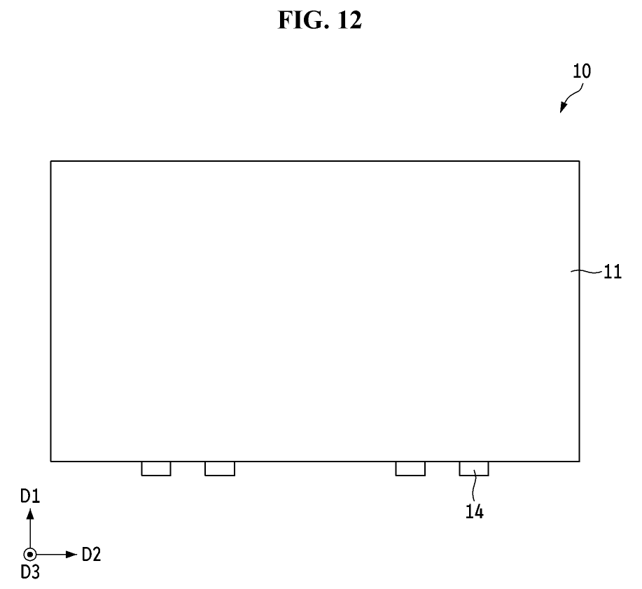

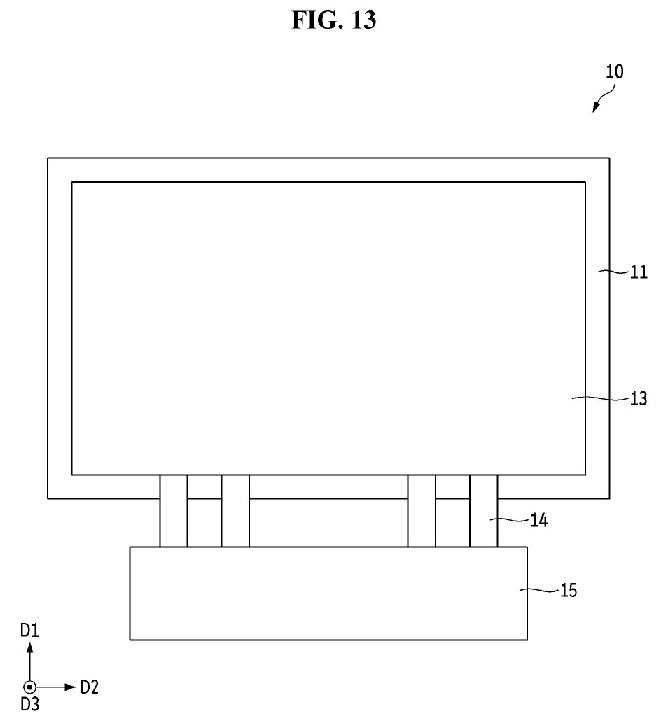

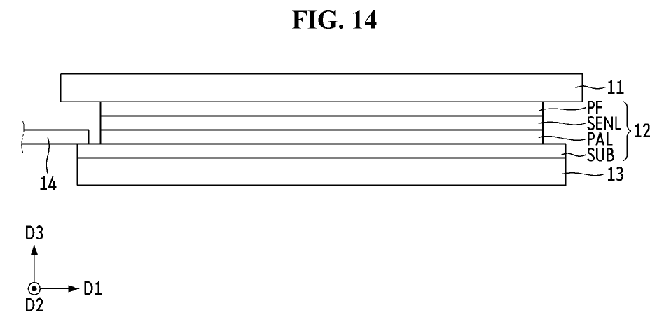

FIG. 12 is a plan view illustrating a bent state of a connection member of a display device manufactured by the thin-film-forming apparatus according to one or more embodiments of the present disclosure. FIG. 13 is a view illustrating a state in which the connection member in FIG. 12 is unfolded. FIG. 14 is a partial side view of FIG. 13.

A display device 10 manufactured by the thin-film-forming apparatus 100 according to one or more embodiments of the present disclosure may be a light-emitting display device, such as an organic light-emitting display device using an organic light-emitting diode (LED), a quantum dot light-emitting display device including a quantum dot light-emitting layer, an inorganic light-emitting display device including an inorganic semiconductor, and a micro light-emitting display device using a micro light-emitting diode (LED). Hereinafter, it is mainly described that the display device 10 is the organic light-emitting display device, but the present disclosure is not limited thereto.

A planar shape of the display device 10 may be a quadrangular shape, such as a rectangle. For example, the display device 10 may have a rectangular planar shape having short sides in the first direction D1 and long sides in the second direction D2. A corner where the short side in the first direction D1 and the long side in the second direction D2 meet may be rounded to have a curvature, or may be formed at a substantially right angle. The planar shape of the display device 10 is not limited to the rectangle, and may be formed in other polygonal, circular, or oval shapes.

Referring to FIGS. 12 to 14, the display device 10 manufactured by the thin-film-forming apparatus 100 according to one or more embodiments of the present disclosure may include a cover window 11, a display panel 12, a panel lower member 13, a connection member 14, and a driving circuit board 15.

The cover window 11 may include a material having high light transmittance. The cover window 11 may include a polymer resin, such as polyimide or glass. The cover window 11 may be attached to a polarizing film PF of the display panel 12 described later by an adhesive material, such as an optically clear adhesive (OCA) film.

The display panel 12 may be located under the cover window 11. The display panel 12 may have a rectangular planar shape having short sides in the first direction D1, and long sides in the second direction D2. In the display panel 12, a corner where the short side in the first direction D1 and the long side in the second direction D2 meet may be formed at a right angle or may be rounded to have a curvature. The display panel 12 may have a planar shape of other quadrangles other than the rectangle and other polygons, circles, ellipses, or irregular shapes other than the quadrangle.

The display panel 12 may include a display area in which a plurality of light-emitting areas that emit light are located and a non-display area located around the display area. The non-display area may surround the display area. A plurality of display pads may be located in a non-display area on one edge of the display panel 12.

The display panel 12 may include a substrate SUB, a display (e.g., display unit) PAL, a sensor layer (e.g., sensor unit) SENL, and a polarizing film PF.

The substrate SUB may include an insulating material, such as glass, quartz, or a polymer resin. The substrate SUB may be a rigid substrate or a flexible substrate that may be bent, folded, and rolled.

The display PAL may be located on the substrate SUB. The display PAL may be a layer including a plurality of light-emitting areas that emit light. The display PAL may include a buffer film, a thin film transistor layer on which thin film transistors are located, a light-emitting element layer that emits light, and an encapsulation layer for encapsulating the light-emitting element layer.

The sensor layer SENL may be located on the display PAL. The sensor layer SENL may include sensor electrodes, and may be a layer for sensing whether a user's touch has been made.

The polarizing film PF may be located on the sensor layer SENL. The polarizing film PF may serve to reduce or prevent deterioration in image visibility of the display panel 12 due to reflection of external light. The polarizing film PF may include a linear polarizing plate and a retardation film, such as a λ/4 plate (quarter-wave plate). The phase retardation film may be located on the sensor layer SENL, and the linear polarizing plate may be located on the phase retardation film. The cover window 11 may be located on the polarizing film PF.

The panel lower member 13 may be located under the substrate SUB. The panel lower member 13 may be attached to a lower surface of the substrate SUB through an adhesive member. The adhesive member may be a pressure sensitive adhesive (PSA). The panel lower member 13 may include at least one of a light-absorbing member for absorbing light incident from the outside, a buffer member for absorbing a shock from the outside, and a heat dissipation member for efficiently dissipating heat of the display panel 12.

The light-absorbing member may be located under the substrate SUB. The light-absorbing member blocks transmission of light, thereby reducing or preventing visibility of components beneath the light-absorbing member, such as a driving circuit board 15, from an upper portion of the display panel 12. The light-absorbing member may include a light-absorbing material, such as a black pigment or a black dye.

The buffer member may be located under the light-absorbing member. The buffer member absorbs the external shock to reduce or prevent damage to the display panel 12. The buffer member may be formed as a single layer or a plurality of layers. For example, the buffer member may include a polymer resin, such as polyurethane, polycarbonate, polypropylene, or polyethylene, or may include a material having elasticity, such as a sponge made by foaming and molding rubber, urethane-based materials, or acrylic-based materials.

The heat dissipation member may be located under the buffer member. The heat dissipation member may include a first heat dissipation layer including graphite or carbon nanotubes, and a second heat dissipation layer formed of a thin metal film, such as copper, nickel, ferrite, or silver that may shield electromagnetic waves and that has excellent thermal conductivity.

The connection member 14 may be electrically connected to the plurality of display pads of the display panel 12 through a conductive adhesive member, such as an anisotropic conductive film. As a result, the display panel 12 and the connection member 14 may be electrically connected.

In addition, the connection member 14 may be connected to a plurality of circuit pads of the driving circuit board 15 through a conductive adhesive member, such as an anisotropic conductive film. As a result, the connection member 14 and the driving circuit board 15 may be electrically connected.

The connection member 14 may be a flexible printed circuit board or a chip on film.

The driving circuit board 15 may be located under the panel lower member 13 when the connection member 14 is bent. The driving circuit board 15 may be a flexible printed circuit board (FPCB) that may be bent, a rigid printed circuit board (PCB) that is hard and that is not easily bent, or a composite printed circuit board including both the rigid printed circuit board and the flexible printed circuit board.

In one or more embodiments, the driving circuit board 15 may process a signal converted by a control circuit board, and may transmit the processed signal to the display panel 12. The driving circuit board 15 may be electrically connected to the display panel 12 by the connection member 14.

The display device may be applied to various electronic devices. An electronic device according to one or more embodiments may include the display device described above, and may further include a module or device having additional functions in addition to the display device.

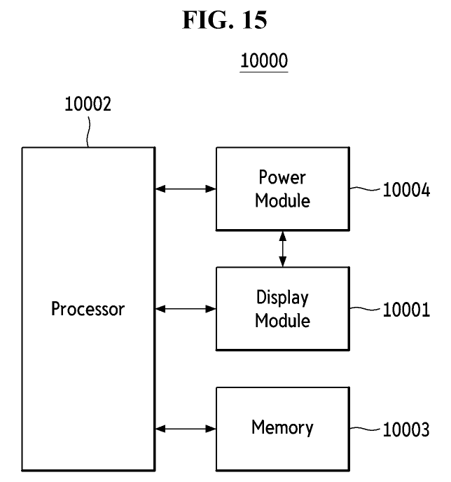

FIG. 15 is a block diagram of an electronic device according to one or more embodiments.

Referring to FIG. 15, an electronic device 10000 according to one or more embodiments may include a display module 10001, a processor 10002, a memory 10003, and a power module 10004.

The processor 10002 may include at least one of a central processing unit (CPU), an application processor (AP), a graphic processing unit (GPU), a communication processor (CP), an image signal processor (ISP), or a controller.

Data information necessary for an operation of the processor 10002 or the display module 10001 may be stored in the memory 10003. When the processor 10002 executes an application stored in the memory 10003, image data signals and/or input control signals may be transmitted to the display module 10001, and the display module 10001 may process the provided signals, and may output image information through a display screen.

The power module 10004 may include a power supply module, such as a power adapter or a battery device, and a power conversion module that converts power supplied by the power supply module to generate power required for an operation of the electronic device 10000.

At least one of the components of the electronic device 10000 described above may be included in the display device according to the above-described embodiments. In addition, some of the individual modules functionally included within one module may be included within the display device, while others may be provided separately from the display device. For example, the display device includes the display module 10001, and the processor 10002, the memory 10003, and the power module 10004 may be provided in the form of other devices within the electronic device 10000 other than the display device.

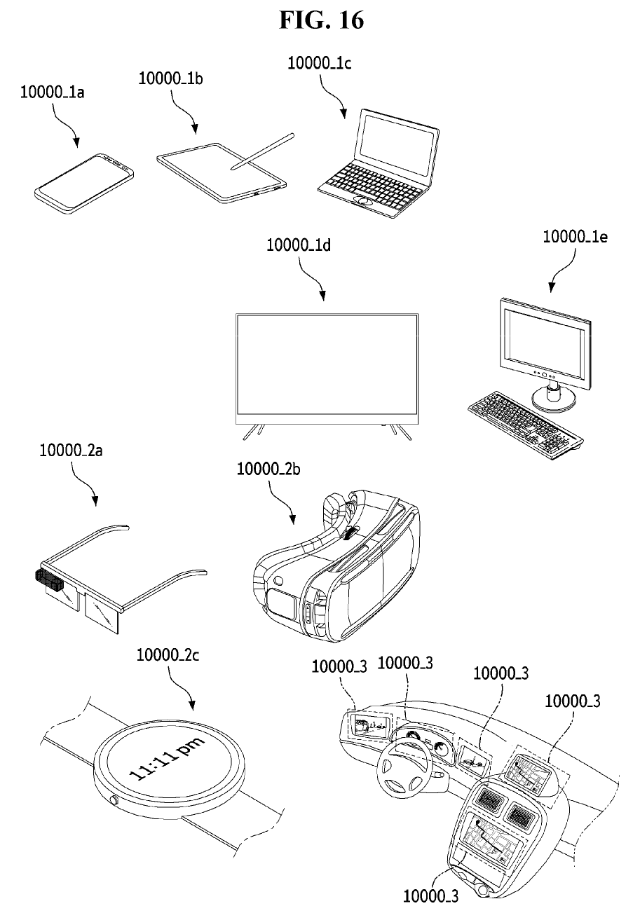

FIG. 16 illustrates schematic diagrams of electronic devices according to various embodiments.

Referring to FIG. 16, various electronic devices to which the display device according to the embodiments is applied may include not only an image display electronic device, such as a smart phone 10000_1a, a tablet PC 10000_1b, a laptop 10000_1c, a TV 10000_1d, and a desk monitor 10000_1e, but also a wearable electronic device including a display module, such as a smart glasses 10000_2a, a head mounted display 10000_2b, a smart watch 10000_2c, and the like, and a vehicle electronic device 10000_3 including a display module, such as a Center Information Display (CID), a room mirror display, etc., located on a vehicle’s instrument panel, center fascia, or dashboard.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A thin-film-forming apparatus comprising:
an electrostatic chuck for supporting a substrate, and comprising:
a base portion;
electrode patterns on the base portion; and
ground patterns on the base portion and spaced apart from the electrode patterns;
a supply nozzle for supplying a chemical onto the substrate; and
a power supply for supplying power to the electrostatic chuck, and for selectively supplying power to one of the electrode patterns.

2. The thin-film-forming apparatus of claim 1, wherein the electrode patterns and the ground patterns are alternately arranged with each other.

3. The thin-film-forming apparatus of claim 1, wherein the electrode patterns and the ground patterns extend in a first direction, and
wherein the electrode patterns and the ground patterns are spaced apart from each other in a second direction crossing the first direction.

4. The thin-film-forming apparatus of claim 3, wherein end portions on one side of the electrode patterns extend beyond the base portion in the first direction.

5. The thin-film-forming apparatus of claim 4, wherein the end portions extend in a third direction orthogonal to the first direction and to the second direction to cover a side surface of the base portion.

6. The thin-film-forming apparatus of claim 4, wherein the power supply comprises:
a moving member configured to move in the second direction outside of the base portion; and
a power supply electrode for contacting the end portions according to the movement of the moving member, and for supplying power to the one electrode pattern.

7. The thin-film-forming apparatus of claim 6, wherein the power supply electrode is configured to rotate according to movement of the moving member.

8. The thin-film-forming apparatus of claim 7, wherein the power supply comprises:
a rotation shaft in the power supply electrode;
an upper support member connected to an upper portion of the rotation shaft;
a lower support member connected to a lower portion of the rotation shaft; and
a connection member connecting the upper support member and the lower support member to the moving member.

9. The thin-film-forming apparatus of claim 8, wherein the power supply further comprises an elastic member between the connection member and the moving member and configured to push the power supply electrode toward the base portion.

10. The thin-film-forming apparatus of claim 3, wherein the substrate comprises:
flat portions; and
protruding portions protruding above the flat portions, and alternately arranged with the flat portions.

11. The thin-film-forming apparatus of claim 10, wherein the electrode patterns and the ground patterns respectively overlap the protruding portions.

12. The thin-film-forming apparatus of claim 11, wherein one of the electrode patterns overlaps one of the protruding portions, and
wherein one of the ground patterns overlaps another one of the protruding portions adjacent the one of the protruding portions with the flat portion.

13. The thin-film-forming apparatus of claim 11, wherein the flat portions and the protruding portions extend in the first direction, and are alternately arranged in the second direction.

14. The thin-film-forming apparatus of claim 1, wherein the electrode pattern is configured to receive an alternating current voltage, and
wherein the ground pattern is configured to receive a ground voltage.

15. The thin-film-forming apparatus of claim 1, wherein the electrode patterns and the ground patterns are configured to be retracted into the base portion from an upper surface of the base portion.

16. An electronic device comprising:
a display device manufactured by a thin-film-forming apparatus comprising:
an electrostatic chuck for supporting a substrate, and comprising:
a base portion;
electrode patterns on the base portion; and
ground patterns on the base portion and spaced apart from the electrode patterns;
a supply nozzle for supplying a chemical onto the substrate; and
a power supply for supplying power to the electrostatic chuck, and for selectively supplying power to one of the electrode patterns.

17. The electronic device of claim 16, wherein the electrode patterns and the ground patterns extend in a first direction, and are spaced apart in a second direction crossing the first direction, and
wherein end portions on one side of the electrode patterns extend beyond the base portion in the first direction.

18. The electronic device of claim 17, wherein the power supply comprises:
a moving member configured to move in the second direction outside of the base portion; and
a power supply electrode for contacting the end portion on one side of one of the electrode patterns according to the movement of the moving member, and for supplying power to the one electrode pattern.

19. The electronic device of claim 18, wherein the power supply further comprises:
a rotation shaft in the power supply electrode;
an upper support member connected to an upper portion of the rotation shaft;
a lower support member connected to a lower portion of the rotation shaft; and
a connection member connecting the upper support member and the lower support member to the moving member.

20. The electronic device of claim 19, wherein the power supply further comprises an elastic member between the connection member and the moving member, and configured to push the power supply electrode toward the base portion.
